(19) United States
(12) Patent Application Publication
(10) Pub. No.: US 2010/0237973 A1
(43) Pub. Date: Sep. 23, 2010

(54) SURFACE MOUNT MAGNETIC DEVICE, COIL STRUCTURE THEREOF AND FABRICATING PROCESS THEREOF

(76) Inventors: Jui-Chu Cheng, Taoyuan Hsien (TW); Chen-En Liao, Taoyuan Hsien (TW)

Correspondence Address: AUSTIN RAPP & HARDMAN, 170 South Main Street, Suite 735, SALT LAKE CITY, UT, 84101, US

(21) Appl. No.: 12/486,041

(22) Filed: Jun. 17, 2009

(30) Foreign Application Priority Data
Mar. 20, 2009 (TW) 098109270

(51) Int. Cl. H01F 27/06; H05K 3/34

(52) U.S. Cl. 336/83; 29/840

(57) ABSTRACT

A process for fabricating a surface mount magnetic device includes the following steps. Firstly, a magnetic core assembly and a coil structure are provided. The magnetic core assembly includes a first magnetic part and a second magnetic part. The coil structure includes a main body and multiple pins extended from the main body. Each pin includes a bent part and a contact part. Next, the magnetic core assembly and the coil structure are combined together. The main body of the coil structure is disposed between the first magnetic part and the second magnetic part. The contact parts of the pins are contacted with a first surface of the second magnetic part.

### CLAIM OF PRIORITY

This application claims priority to Taiwanese Patent Application No. 098109270 filed on Mar. 20, 2009.

### FIELD OF THE INVENTION

The present invention relates to a magnetic device, and more particularly to a surface mount magnetic device. The present invention relates to a process for fabricating such a surface mount magnetic device and a coil structure of the surface mount magnetic device.

### BACKGROUND OF THE INVENTION

Magnetic elements such as inductors and transformers are widely used in many electronic apparatuses such as power supply apparatuses or power adapters. Since the power supply apparatuses or power adapters are developed toward minimization and high power, the volumes of the magnetic devices for use in these electronic apparatuses are gradually reduced and the shapes thereof become flatter. Moreover, the magnetic element can be directly arranged on a circuit board according to a surface mount technology (SMT), and thus such a magnetic element is also referred as a surface mount magnetic device.

FIG. A is a schematic view illustrating a process for fabricating a surface mount magnetic device. FIG. B is a schematic assembled view of the surface mount magnetic device of FIG. 1A. Please refer to FIG. 1A and FIG. 1B. An example of the surface mount magnetic device 1 is an inductor. The surface mount magnetic device 1 comprises a magnetic core assembly 10 and a coil structure 11. The magnetic core assembly 10 includes a first magnetic part 101 and a second magnetic part 102. The coil structure 11 includes a main body 110 and multiple pins 111 (e.g. a first pin 111a and a second pin 111b). The pins 111 are horizontally extended from the main body 110 of the coil structure 11. Then, the first magnetic part 101 and the second magnetic part 102 are combined together such that the main body 110 of the coil structure 11 is accommodated within a receptacle of the magnetic core assembly 10. Then, the pins 111 are bent toward the second magnetic part 102 (in the direction indicated as the dotted line) such that the second surfaces 113 of the pins 111 face the top surface of the second magnetic part 102. The resulting structure of the surface mount magnetic device 1 is shown in FIG. 1B. After the first surfaces 112 of the pins 111 are welded onto the solder pads of a circuit board (not shown), the surface mount magnetic device 1 is fixed onto the circuit board.

The surface mount magnetic device 1, however, has some drawbacks. For example, since the pins 111 are bent by a jig (not shown) after the magnetic core assembly 10 and the coil structure 11 are combined together, the magnetic core assembly 10 is readily compressed by the jig and the insulating layers of the pins 111 are possibly scraped off. Under this circumstance, the yield of the surface mount magnetic device 1 is reduced. For avoiding the damage of the magnetic core assembly 10 or the insulating layers resulted from the jig, the pins 111 should be manually bent. The procedure of manually bending the pins 111 is time-consuming and labor-intensive and fails to control the bending degree and evenness of the pins 111. Please refer to FIG. 1B again. If the bending degree of the bent part 115 of the first pin 111a is greater than that of the second pin 111b, the first pin 111a is relatively protruded with respect to the second pin 111a. Under this circumstance, the dimensions of the surface mount magnetic device 1 are possibly over the allowable range. Moreover, when the surface mount magnetic device 1 is mounted on the circuit board, the bent part 115 of the first pin 111a may be contacted with a neighboring electronic component and thus the electrical safety is deteriorated. Since the first contact surfaces 112 of the pins 111a and 111b are not coplanar, the surface mount magnetic device 1 is readily inclined after mounted on the circuit board.

For complying with the magnetic core assembly 10, the pins 111 of the coil structure 10 are partially cut off in some situations. As a consequence, the pins 111 may have feathering edges, which also deteriorates the evenness of the pins 111. In addition, since the end surfaces 114 of the pins are bare after the cutting procedure, the end surfaces 114 of the pins are readily oxidized. For example, the pins 111 made of copper will be oxidized into cupric oxide. As known, cupric oxide has poor solderability. Due to the poor solderability, the pins 111 fail to be securely welded onto the circuit board through a soldering material 12. Since the distance D′ between the first pin 111a and the second pin 111b is not constant and the first contact surfaces 112 of the pins 111a and 111b are not coplanar, the adhesion between the pins 111a, 111b and the solder pads of the circuit board may be insufficient. In other words, the electrical connection and structural connection between the surface mount magnetic device 1 and the circuit board are usually unsatisfactory according to the prior art. Even if the areas of the solder pads are increased, the above problems also occur because the pins 111a, 111b are readily shifted during the welding process. In addition, since the amount of the soldering material 12 fails to be precisely controlled, the pins 111a and 111b possibly fail to be firmly fixed onto the circuit board.

From the above discussion, since the pins 111 are bent after the magnetic core assembly 10 and the coil structure 11 are combined together, the convention process for fabricating the surface mount magnetic device 1 is troublesome and costly. In addition, the yield of the surface mount magnetic device 1 is unsatisfied because of many above-mentioned drawbacks.

Therefore, there is a need of providing an improved surface mount magnetic device so as to obviate the drawbacks encountered from the prior art.

### SUMMARY OF THE INVENTION

It is an object of the present invention to provide a surface mount magnetic device, in which the pins have enhanced evenness so as to be firmly fixed on the circuit board.

Another object of the present invention provides a surface mount magnetic device whose dimensions are precisely controlled.

A further object of the present invention provides a process for fabricating a surface mount magnetic device in a cost-effective and time-saving manner.

In accordance with an aspect of the present invention, there is provided a process for fabricating a surface mount magnetic device. Firstly, a magnetic core assembly and a coil structure are provided. The magnetic core assembly includes a first magnetic part and a second magnetic part. The coil structure includes a main body and multiple pins extended from the main body. Each pin includes a bent part and a contact part. Next, the magnetic core assembly and the coil structure are combined together. The main body of the coil structure is disposed between the first magnetic part and the second magnetic part. The contact parts of the pins are contacted with a first surface of the second magnetic part.

In accordance with another aspect of the present invention, there is provided a surface mount magnetic device disposed on a circuit board. The surface mount magnetic device includes a magnetic core assembly and a coil structure. The magnetic core assembly includes a first magnetic part and a second magnetic part. The second magnetic part includes a first surface and a second surface. A receptacle is defined by the first magnetic part and the second surface of the second magnetic part. The coil structure includes a main body accommodated within the receptacle and multiple pins extended from the main body. The pins include respective bent parts and respective contact parts. The contact parts of the pins are contacted with the first surface of the second magnetic part, and have respective end surfaces and respective first contact surfaces. The first contact surfaces are contacted with the circuit board. The end surfaces and the first contact surfaces are coated with a soldering material.

In accordance with a further aspect of the present invention, there is provided a coil structure of a surface mount magnetic device. The surface mount magnetic device is disposed on a circuit board and includes a magnetic core assembly. The coil structure includes a main body and multiple pins. The main body is accommodated within the magnetic core assembly. The pins are extended from the main body. Each pin includes a bent part and a contact part. The contact part is separated from the main body by a gap through the bent part. The magnetic core assembly is partially embedded into the gap. The contact part has an end surface and a first contact surface. The first contact surface is contacted with the circuit board. The end surface and the first contact surface are coated with a soldering material.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic view illustrating a process for fabricating a surface mount magnetic device;

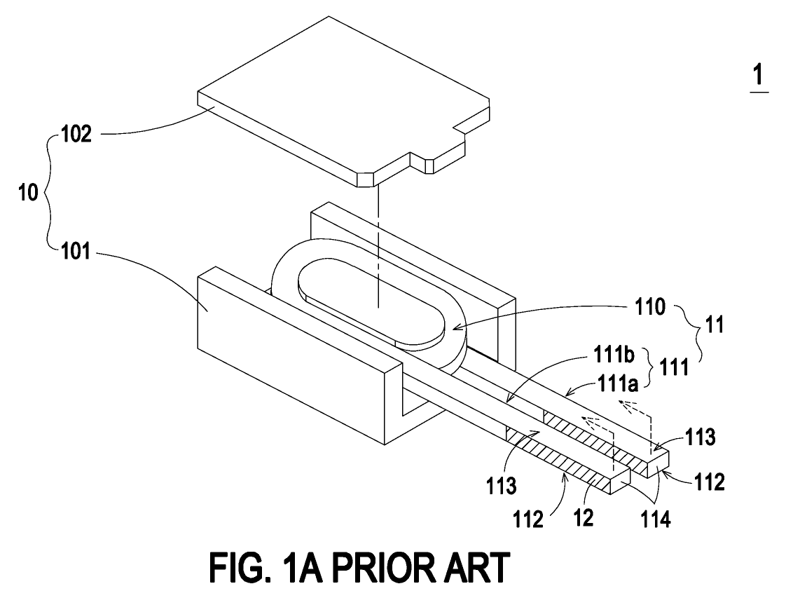

FIG. 1B is a schematic assembled view of the surface mount magnetic device of FIG. 1A;

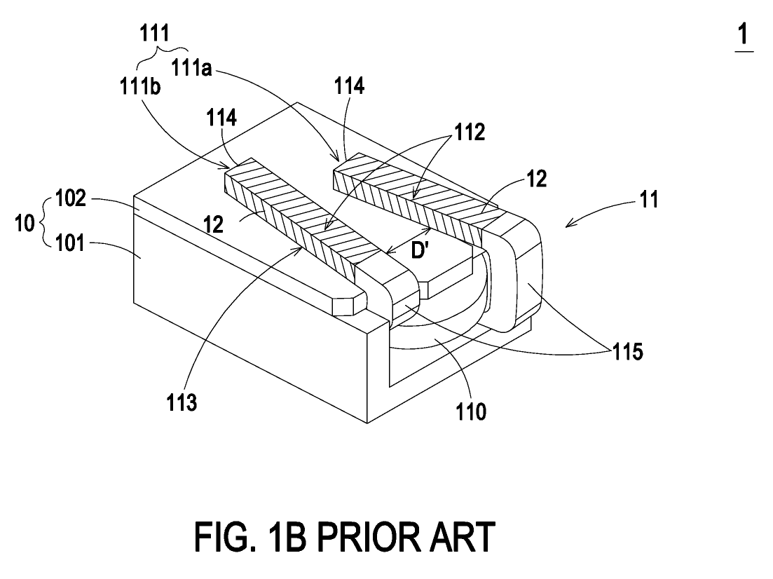

FIG. 2 schematically illustrates a process for fabricating a surface mount magnetic device according to a first embodiment of the present invention;

FIG. 3A is a schematic exploded view of the surface mount magnetic device according to the first embodiment of the present invention;

FIG. 3B is a schematic assembled view of the surface mount magnetic device shown in FIG. 3A;

FIG. 3C is a schematic front view of the surface mount magnetic device shown in FIG. 3B;

FIG. 3D is a schematic side view of the surface mount magnetic device shown in FIG. 3B; and

FIG. 4 is a schematic perspective view illustrating the surface mount magnetic device of FIG. 3B to be fixed on a circuit board.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

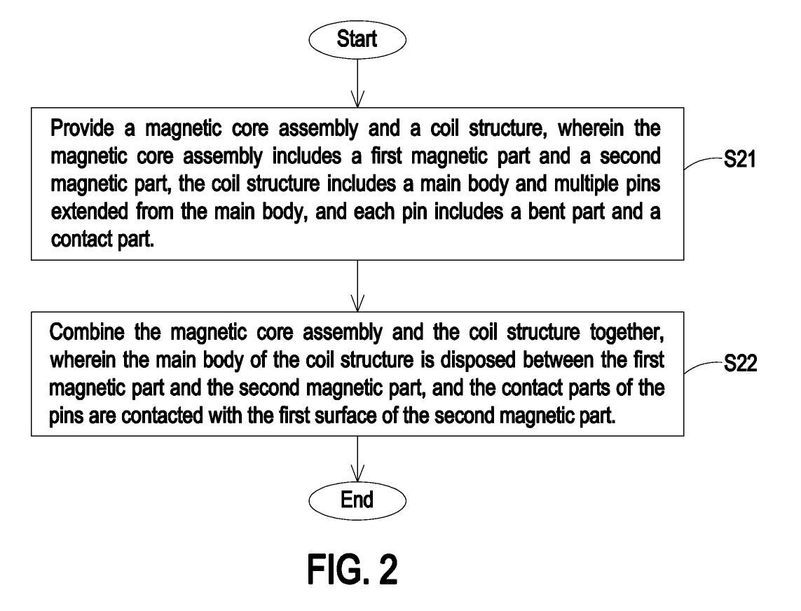

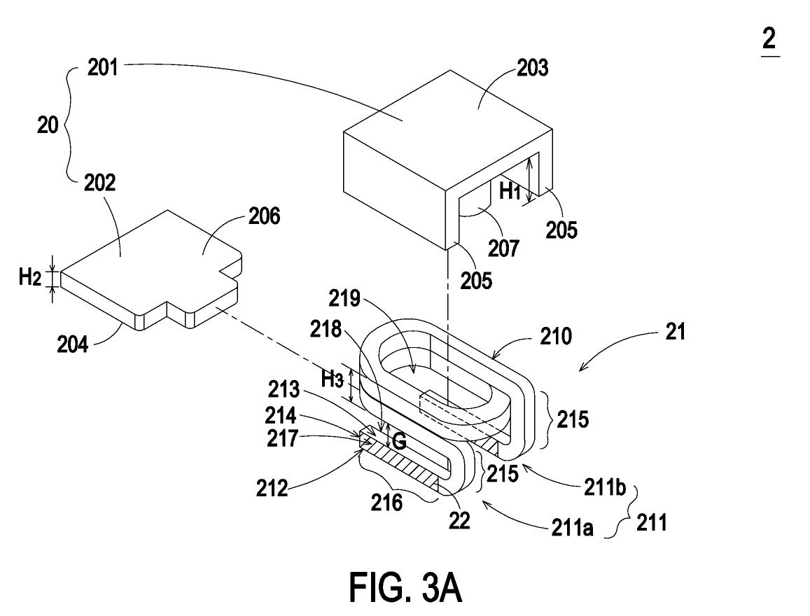

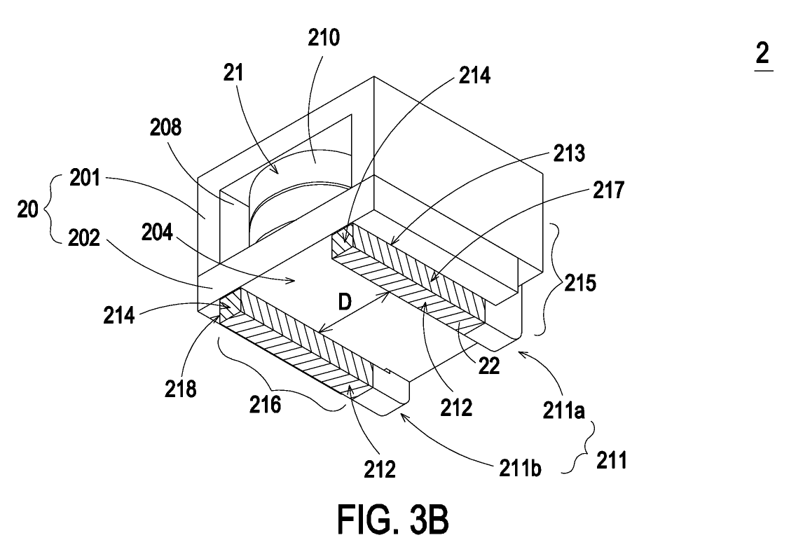

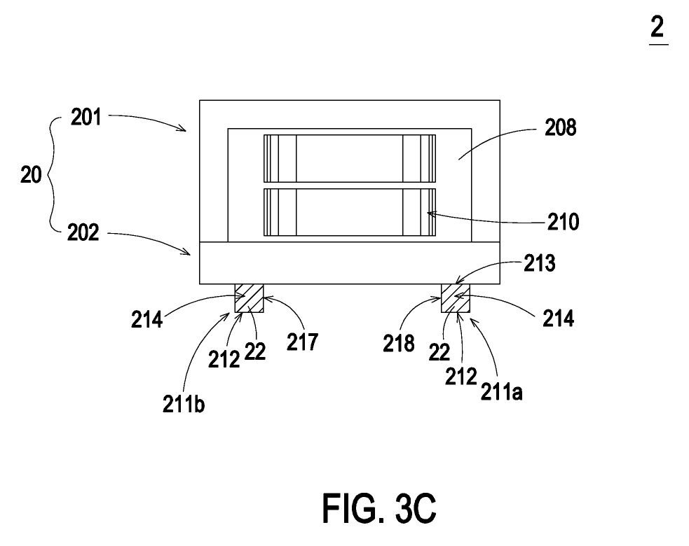

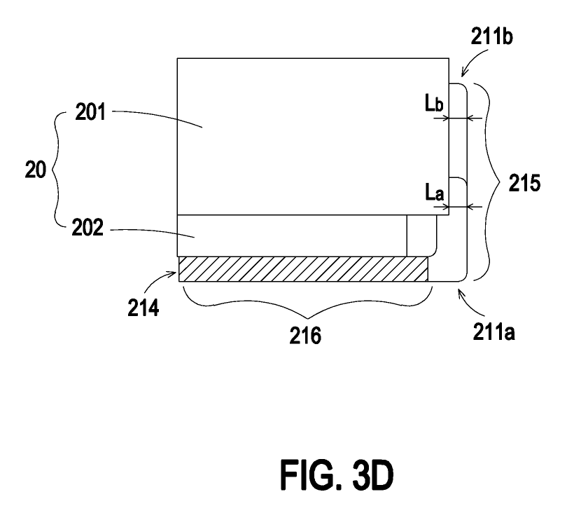

FIG. 2 schematically illustrates a process for fabricating a surface mount magnetic device according to a first embodiment of the present invention. FIG. 3A is a schematic exploded view of the surface mount magnetic device according to the first embodiment of the present invention. FIG. 3B is a schematic assembled view of the surface mount magnetic device shown in FIG. 3A. Hereinafter, the process for fabricating the surface mount magnetic device 2 will be illustrated with reference to FIG. 2A, FIG. 3A and FIG. 3B.

First of all, a magnetic core assembly 20 and a coil structure 21 are provided (Step S21). The magnetic core assembly 20 includes a first magnetic part 201 and a second magnetic part 202. The coil structure 21 includes a main body 210 and multiple pins 211 extended from the main body 210. Each pin 211 includes a bent part 215 and a contact part 216. Then, the magnetic core assembly 20 and the coil structure 21 are combined together (Step S22). The main body 210 of the coil structure 21 is disposed between the first magnetic part 201 and the second magnetic part 202 of the magnetic core assembly 20. The contact parts 216 of the pins 211 are contacted with the first surface 204 of the second magnetic part 202.

Pleas refer to FIG. 2 and FIG. 3A again. The first magnetic part 201 of the magnetic core assembly 20 comprises a top surface 203, two leg portions 205 and a middle portion 207. The two leg portions 205 are respectively protruded from two opposite edges of the top surface 203. The middle portion 207 is protruded from the middle of the top surface 203 and arranged between the two leg portions 205. Each of the two leg portions 205 and the middle portion 207 has the same height H1. The shape of the middle portion 207 is adjusted to mate with the main body 210 of the coil structure 21. The second magnetic part 202 is a flat magnetic core having a height H2. The second magnetic part 202 has a first surface 204 and a second surface 206, which are opposed to each other. In this embodiment, the first magnetic part 201 is an E-core and the second magnetic part 202 is an I-core.

In the step S21, the coil structure 21 is produced by bending a metallic wire having a rectangular cross-section area in the assistance of a jig (not shown). An example of the metallic wire is an enameled copper wire. It is preferred that the pins 211 are integrally formed with the main body 210. In this embodiment, the main body 210 of the coil structure 21 has a ring-shaped profile mating with the shape of the middle portion 207 of the first magnetic part 201. As such, a channel 219 is defined by the main body 210 of the coil structure 21 along the axial direction. The dimension of the channel 219 mates with that of the middle portion 207. For example, if the middle portion 207 of the first magnetic part 201 is elliptical, the channel 219 has an elliptical profile. As such, the middle portion 207 of the first magnetic part 201 will be embedded in the channel 219 of the coil structure 21. Moreover, the middle portion 207 of the first magnetic part 201 may have a circular or square profile so long as the dimension of the channel 219 mates with that of the middle portion 207. In addition, the main body 210 could be bent by multiple loops. In this embodiment, the main body 210 has a two-loop ring-shaped configuration. As the loop number of the main body 210 is increased, the height H3 of the main body 210 is increased. In addition, the height H3 of the main body 210 is equal to or slightly smaller than the height H1 of the leg portions 205 of the first magnetic part 201.

Please refer to FIG. 3A again. In this embodiment, the coil structure 21 includes two pins 211 (e.g. a first pin 211a and a second pin 211b). The main body 210 is arranged between the first pin 211a and the second pin 211b. The first pin 211a and the second pin 211b have sufficient length to comply with the height H3 of the main body 210 and the height H2 of the second magnetic part 202. In the assistance of a jig (not shown), the first pin 211a and the second pin 211b are bent to have respective bent parts 215 and respective contact parts 216. The bent part 215 is arranged between the main body 210 and the contact part 216, and has a curvy profile. As such, the contact part 216 is separated from the main body 210 by a gap G through the bent part 215. The height of the gap G is substantially equal to the height H2 of the second magnetic part 202 such that the second magnetic part 202 is permitted to be inserted into the gap G.

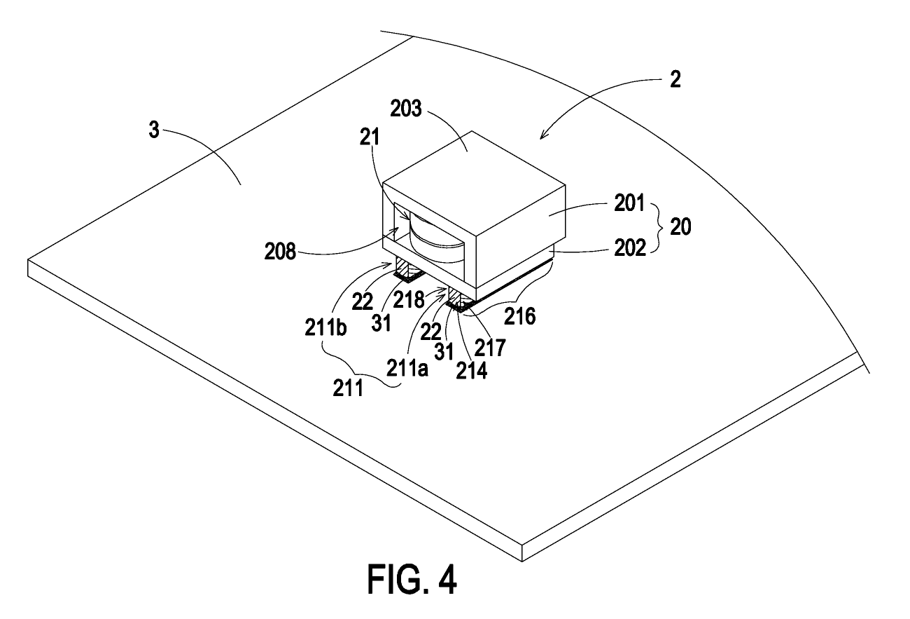

Take the first pin 211a for example. The contact part 216 of the first pin 211a has a first contact surface 212, a second contact surface 213, an end surface 214, a first lateral surface 217 and a second lateral surface 218. The end surface 214 is disposed at the tip of the first pin 211a and has a rectangular cross-section. The first contact surface 212 and the second contact surface 213 are opposed to each other and connected with the end surface 214. The second contact surface 213 faces the main body 210 of the coil structure 21. Through the first contact surface 212, the surface mount magnetic device 2 is fixed onto a circuit board 3 (see FIG. 4). The first lateral surface 217 and the second lateral surface 218 are opposed to each other and connected with the end surface 214. The configurations of the second pin 211b are identical to those of the first pin 211a, and are not redundantly described herein.

For welding the surface mount magnetic device 2 on the circuit board 3 (see FIG. 4), the insulating layers coated on the first contact surfaces 212 and the end surfaces 214 of the pins 211 need to be removed. Next, a soldering material (e.g. tin paste) is applied on the junction between the solder pads of the circuit board 3 and the first contact surfaces 212 of the pins 211. For enhancing the adhesion between the pins 211 and the circuit board 3, the soldering material is also partially applied on the end surfaces 214, the first lateral surfaces 217 and the second lateral surfaces 218.

Please refer to FIG. 3B again. For combining the magnetic core assembly 20 and the coil structure 21 together, the middle portion 207 of the first magnetic part 201 is embedded into the channel 219 of the main body 210, so that the middle portion 207 of the first magnetic part 201 is sheathed by the main body 210. Since the height H3 of the main body 210 is equal to or slightly smaller than the height H1 of the leg portions 205 of the first magnetic part 201, the main body 210 is accommodated within the receptacle 208 between the first magnetic part 201 and the second magnetic part 202. In addition, since the height of the gap G between the contact part 216 of the pin 211 and the main body 210 is substantially equal to the height H2 of the second magnetic part 202, the leg portions 205 and the middle portion 207 of the first magnetic part 201 are in contact with the second surface 206 of the second magnetic part 202 after the second magnetic part 202 is inserted into the gap G. At the same time, the second contact surfaces 213 of the contact parts 216 of the pins 211 are contacted with the first surface 204 of the second magnetic part 202. For facilitating securely combining the first magnetic part 201 and the second magnetic part 202 again, an adhesive could be applied on the junction between the first magnetic part 201 and the second magnetic part 202. Optionally, an adhesive could be applied on the junction between the second contact surfaces 213 of the pins 211 and the first surface 204 of the second magnetic part 202 in order to facilitate securely combining the main body 210 of the coil structure 21 and the second magnetic part 202 together.

FIG. 3C is a schematic front view of the surface mount magnetic device shown in FIG. 3B. FIG. 3D is a schematic side view of the surface mount magnetic device shown in FIG. 3B. Since the first pin 211a and the second pin 211b are bent to have respective bent parts 215 and respective contact parts 216 in the assistance of a jig (not shown), the evenness of the contact parts 216 will be increased in comparison with the prior art technology. In other words, the contact parts 216 of the pins 211a and 211b are substantially parallel with each other (see FIG. 3B) but separated from each other by a constant distance D. Moreover, the first contact surfaces 212 of the contact parts 216 of the pins 211a and 211b are substantially coplanar (see FIG. 3C), thereby increasing the evenness of the contact parts 216. In an embodiment, the height difference between the first contact surfaces 212 of adjacent pins 211 is smaller than 0.1 mm in order to prevent from largely increasing the overall height of the surface mount magnetic device 2.

Moreover, since the first pin 211a and the second pin 211b have sufficient length to comply with the height H3 of the main body 210 and the height H2 of the second magnetic part 202, the bending degree of the bent parts 215 and the lengths of the contact parts 216 could be precisely controlled. Please refer to FIG. 3D. The bent parts 215 of the first pin 211a and the second pin 211b have the same bending degree. In addition, the thickness La of the first pin 211a is substantially equal to the thickness Lb of the second pin 211b. In other words, the dimensions of the surface mount magnetic device 2 are precisely controlled.

Moreover, since the first pin 211a and the second pin 211b have sufficient length to comply with the height H3 of the main body 210 and the height H2 of the second magnetic part 202, the pins 211 do not need to be removed during the fabricating process of the surface mount magnetic device 2. In other words, the end surfaces 214 of the pins 214 are no longer oxidized into cupric oxide. Under this circumstance, the solderability is enhanced in comparison with the prior art technology. Moreover, since the areas of the end surface 214, the first contact surface 212, the first lateral surface 217 and //the second lateral surface 218 of the first pin 211 a are substantially identical to those of the second pin 211b, the amount of the soldering material 22 could be precisely controlled.

FIG. 4 is a schematic perspective view illustrating the surface mount magnetic device of FIG. 3B to be fixed on a circuit board. As mentioned above, the lengths of the contact parts 216 of the pins 211a and 211b are equal, the amount of the soldering material 22 is precisely controlled, and the first contact surfaces 212 of the contact parts 216 of the pins 211a and 211b are substantially coplanar. After the first surfaces 212 of the pins 111 are welded onto the solder pads of the circuit board 3 by the soldering material 22, the surface mount magnetic device 2 is securely fixed onto the circuit board 3 while maintaining good evenness. Under this circumstance, the top surface 203 of the first magnetic part 201 of the magnetic core assembly 20, the first contact surfaces 212 of the contact parts 216 of the pins 211 and the surface of the circuit board 3 are substantially parallel with each other. Moreover, since the end surfaces 214, the first contact surfaces 212, the first lateral surfaces 217 and the second lateral surfaces 218 of the pins 211 could be wetted by the soldering material 22, the amount of the soldering material 22 is increased and the adhesion between the surface mount magnetic device 2 and the circuit board 3 is enhanced.

From the above description, since the length of the pin of the coil structure is previously determined and the pin is processed to create the bent part and the contact part before the magnetic core assembly and the coil structure are combined together, the process for fabricating the surface mount magnetic device according to the present invention is simplified, time-saving and cost-effective. In addition, since the procedure of cutting off the pins is exempted, the problems of scraping the coil structure, damaging the magnetic core assembly and/or causing feathering edges are overcome. Moreover, since the end surfaces of the pins are no longer oxidized into cupric oxide, the solderability is enhanced. The end surfaces, the first contact surfaces, the first lateral surfaces and the second lateral surfaces of the pins could be wetted by the soldering material, and thus the adhesion between the surface mount magnetic device and the circuit board is enhanced.

Moreover, since the bending degree of the bent parts of the pins and the lengths of the contact parts of the pins are precisely controlled, the dimensions of the surface mount magnetic device could be precisely controlled. Due to the good evenness of the pins, the surface mount magnetic device of the present invention can be securely fixed onto the circuit board. In other words, since the contact parts of the pins are precisely aligned with corresponding contact pads of the circuit board, the problems of shifting the pins during the welding process will be overcome.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process for fabricating a surface mount magnetic device, said process comprising steps of:
providing a magnetic core assembly and a coil structure, wherein said magnetic core assembly includes a first magnetic part and a second magnetic part, said coil structure includes a main body and multiple pins extended from said main body, and each pin includes a bent part and a contact part; and
combining said magnetic core assembly and said coil structure together, wherein said main body of said coil structure is disposed between said first magnetic part and said second magnetic part, and said contact parts of said pins are contacted with a first surface of said second magnetic part.

2. The process according to claim 1 wherein said first magnetic part of said magnetic core assembly includes a top surface, a middle portion and two leg portions, and said second magnetic part of said magnetic core assembly includes a first surface and a second surface, wherein said middle portion and said two leg portions are protruded from said top surface of said first magnetic part, and said middle portion is arranged between said two leg portions.

3. The process according to claim 2 wherein a channel is defined by said main body of said coil structure, and said contact part of said pin is separated from said main body by a gap through said bent part.

4. The process according to claim 3 wherein said step of combining said magnetic core assembly and said coil structure together comprises sub-steps of:
embedding said middle portion of said first magnetic part into said channel such that said middle portion of said first magnetic part is sheathed by said main body; and
inserting said second magnetic part into said gap such that said second surface of said second magnetic part is contacted with said two leg portions and said middle portion of said first magnetic part, wherein said coil structure is accommodated within a receptacle defined by said first magnetic part and said second magnetic part, and said contact parts of said pins are contacted with said first surface of said second magnetic part.

5. The process according to claim 1 wherein said contact part of each pin comprises:
an end surface;
a first contact surface disposed beside said end surface and contacted with a circuit board;
a second contact surface disposed beside said end surface and opposed to said first contact surface, and facing said main body of said coil structure;
a first lateral surface disposed beside said end surface; and
a second lateral surface disposed beside said end surface and opposed to said first lateral surface, wherein said end surface, said first and second contact surfaces, and said first and second lateral surfaces are coated with a soldering material.

6. The process according to claim 5 wherein said first contact surfaces of said contact parts of said pins are coplanar.

7. The process according to claim 1 wherein said contact parts of said pins are substantially parallel with each other and have the same length.

8. A surface mount magnetic device disposed on a circuit board, said surface mount magnetic device comprising:
a magnetic core assembly comprising a first magnetic part and a second magnetic part, wherein said second magnetic part includes a first surface and a second surface, and a receptacle is defined by said first magnetic part and said second surface of said second magnetic part; and
a coil structure comprising a main body accommodated within said receptacle and multiple pins extended from said main body, wherein said pins include respective bent parts and respective contact parts, said contact parts of said pins are contacted with said first surface of said second magnetic part and have respective end surfaces and respective first contact surfaces, said first contact surfaces are contacted with said circuit board, and said end surfaces and said first contact surfaces are coated with a soldering material.

9. The surface mount magnetic device according to claim 8 wherein said main body of said coil structure has a multi-loop ring-shaped configuration, and a channel is defined by said main body of said coil structure.

10. The surface mount magnetic device according to claim 8 wherein said contact part of said pin is separated from said main body by a gap through said bent part, and said second magnetic part of said magnetic core assembly is inserted into said gap.

11. The surface mount magnetic device according to claim 8 wherein said contact part of each pin further comprises:
a second contact surface opposed to said first contact surface, and facing said first surface of said second magnetic part, wherein said first and second contact surfaces are disposed beside said end surface;
a first lateral surface disposed beside said end surface; and
a second lateral surface disposed beside said end surface and opposed to said first lateral surface, wherein said first and second lateral surfaces are coated with said soldering material.

12. The surface mount magnetic device according to claim 8 wherein said first magnetic part of said magnetic core assembly includes a top surface, a middle portion and two leg portions, said middle portion and said two leg portions are protruded from said top surface of said first magnetic part, and said middle portion is arranged between said two leg portions and aligned with said channel of said main body of said coil structure.

13. The surface mount magnetic device according to claim 12 wherein said top surface of said first magnetic part of said magnetic core assembly, said first surfaces of said contact parts of said pins and said circuit board are substantially parallel with each other.

14. The surface mount magnetic device according to claim 8 wherein said first contact surfaces of said contact parts of said pins are coplanar.

15. The surface mount magnetic device according to claim 8 wherein said contact parts of said pins are substantially parallel with each other and have the same length.

16. A coil structure of a surface mount magnetic device, said surface mount magnetic device is disposed on a circuit board and including a magnetic core assembly, said coil structure comprising:
a main body accommodated within said magnetic core assembly; and multiple pins extended from said main body, wherein each pin includes a bent part and a contact part, said contact part is separated from said main body by a gap through said bent part, said magnetic core assembly is partially embedded into said gap, said contact part has an end surface and a first contact surface, said first contact surface is contacted with said circuit board, and said end surface and said first contact surface are coated with a soldering material.

17. The coil structure according to claim 16 wherein said main body of said coil structure has a multi-loop ring-shaped configuration, and a channel is defined by said main body of said coil structure.

18. The coil structure according to claim 16 wherein said contact part of each pin further comprises:
a second contact surface opposed to said first contact surface, and facing said first surface of said second magnetic part, wherein said first and second contact surfaces are disposed beside said end surface;
a first lateral surface disposed beside said end surface; and
a second lateral surface disposed beside said end surface and opposed to said first lateral surface, wherein said first and second lateral surfaces are coated with said soldering material.

19. The coil structure according to claim 16 wherein said first contact surfaces of said contact parts of said pins are coplanar.

20. The coil structure according to claim 16 wherein said contact parts of said pins are substantially parallel with each other and have the same length.
